(19) United States
(12) Patent Application Publication
(10) Pub. No.: US 2025/0244362 A1
(43) Pub. Date: Jul. 31, 2025

(54) FOUR-TERMINAL CURRENT MEASUREMENT SHUNT RESISTOR ASSEMBLY

(71) Applicant: Vacon Oy, Vaasa (FI)

(72) Inventor: Juha Hautamaki, Vaasa (FI)

(21) Appl. No.: 18/978,255

(22) Filed: Dec. 12, 2024

(30) Foreign Application Priority Data
Jan. 25, 2024 (DE) 102024102153.5

(51) Int. Cl. G01R 1/20; G01R 19/00

(52) U.S. Cl. CPC G01R 1/203; G01R 19/0092

(57) ABSTRACT

A four-terminal current measurement shunt resistor assembly including a shunt resistor portion, a sensing loop, and a PCB portion, wherein the shunt resistor portion includes two low resistance portions connected by a high resistance portion and wherein the PCB portion connects the two low resistance portions to each other via two contact points.

### CROSS-REFERENCE TO RELATED APPLICATION

This application claims foreign priority benefits under 35 U.S.C. § 119 to German Patent Application No. 102024102153.5 filed on Jan. 25, 2024, the content of which is hereby incorporated by reference in its entirety.

### TECHNICAL FIELD

The present invention pertains to a four-terminal current measurement shunt resistor assembly comprising a shunt resistor portion, a sensing loop, and a PCB portion, wherein the shunt resistor portion comprises two low resistance portions connected by a high resistance portion and wherein the PCB portion connects the two low resistance portions to each other via two contact points.

### BACKGROUND

Shunt resistor assemblies are used for current measurements. Such measurements may occur at high frequencies, at which problematic inductivity and skin effects dominate the characteristics and output of the shunt resistor and reduce its performance. Known shunt resistors may comprise coaxial shunt structures made of U-shaped components. Such known shunt resistors can technically perform well, but they are complex, difficult to mass produce and expensive.

### SUMMARY

The aim of the present invention is to provide an improved resistor system overcoming the above outlined problems and ensuring the correct functioning of the shunt resistor even at high frequencies.

This aim is achieved by a four-terminal current measurement shunt resistor according to claim 1. Advantageous embodiments of the invention are subject to the sub-claims.

Claim 1 refers to a four-terminal current measurement shunt resistor assembly comprising a shunt resistor portion, a sensing loop, and a PCB portion, wherein the shunt resistor portion comprises two low resistance portions connected to each other by a high resistance portion and wherein the PCB portion connects the two low resistance portions to each other via two contact points. The two contact points are the sensing terminals of the shunt resistor assembly.

The present invention therefore centres on the use of a special geometry of the assembly in the claimed potential measurement circuit and its implementation as a printed circuit board structure. The printed circuit board structure facilitates the addition of possible further compensation components and other components. The present invention allows for improved behaviour at high frequency current measurements using a strip shaped shunt resistor. It offers a simple and cost-efficient solution to the above outlined problems, is easily mass-produced, and provides a good frequency response. Furthermore, it allows for an extension of the usable frequency range.

In a preferred embodiment of the invention, the low resistance portions are made of copper and/or the high resistance portion is made of manganin, i.e. an alloy comprising 84.2%±2.0% copper, 12.1%±2.0% manganese, and 3.7%±2.0% nickel.

In another preferred embodiment of the invention, the sensing loop is arranged in a symmetrical manner. In particular, the sensing loop may be of a rectangular shape.

In another preferred embodiment of the invention, the PCB portion is mounted preferably directly to the shunt resistor portion via contact points in the middle of the shunt resistor portion and/or conductors within the PCB portion are routed across the shunt resistor portion at a distance from its edge corresponding to 20%±5% of the width of the shunt resistor portion.

In another preferred embodiment of the invention, the PCB portion comprises the sensing loop, a high frequency compensation network, a Delta-Sigma AD-converter, current measurement circuitry, an IGBT driver, and/or a drive.

In another preferred embodiment of the invention, the shunt resistor portion comprises a self-inductive portion coupled in series with a resistive shunt portion.

In a particularly preferred embodiment of the invention, the shunt resistor portion comprises a voltage sensing inductive portion coupled in series with the high frequency compensation network.

In another particularly preferred embodiment of the invention, the high frequency compensation network comprises an RC filter to block certain output frequencies. The blocked frequencies may be selected depending on the actual requirements of the current shunt resistor assembly.

In another preferred embodiment of the invention, the shunt resistor portion is of a substantially rectangular shape, wherein its external edges are preferably continuous and straight.

In another preferred embodiment of the invention, one of the contact points is aligned with the sensing loop. The alignment of the contact point with the sensing loop provides a symmetrical arrangement of the components, thereby enhancing the performance of the device.

### BRIEF DESCRIPTION OF THE DRAWINGS

Further details and advantages of the invention are described with reference to the embodiments shown in the figures, the features of which may be part of the invention in any possible combination. The figures show:

FIG. 1: the principle for optimal potential lead placement of the current measurement shunt resistor assembly;

FIG. 2: a model of the current measurement shunt resistor assembly; and

FIG. 3: a perspective view of the model of the current measurement shunt resistor assembly.

### DETAILED DESCRIPTION

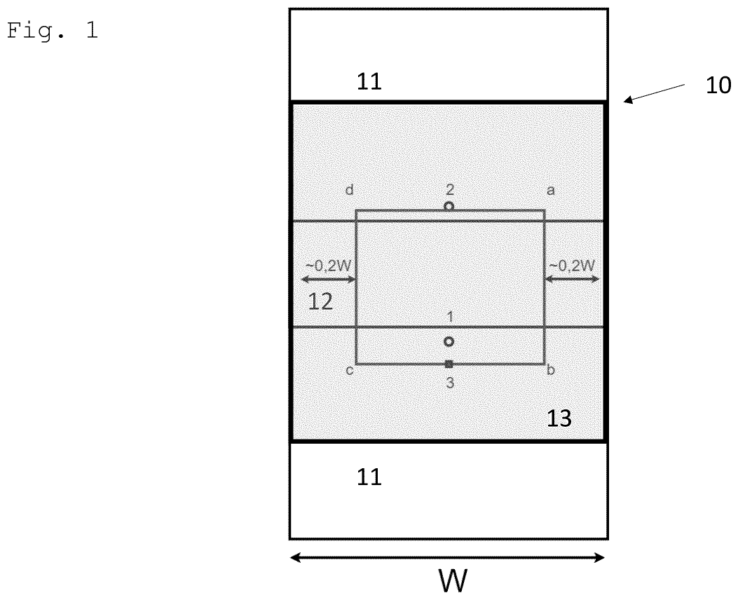

FIG. 1 shows the principle for optimal potential lead placement of the presently described current measurement shunt resistor assembly. The current measurement shunt resistor assembly comprises four terminals and a shunt resistor portion 10, a sensing loop 3, b, a, 2, d, c, 3, and a PCB 13 portion shown as a grey shaded area. The shunt resistor portion 10 comprises two low resistance portions 11 connected by a high resistance portion 12. The PCB 13 portion connects the two low resistance portions 11 to each other via two contact points 1, 2.

The low resistance portions 11 may be made of copper or some other metal such as aluminium. The high resistance portion 12 may be made of manganin, i.e. an alloy comprising 84.2%±2.0% copper, 12.1%±2.0% manganese, and 3.7%±2.0% nickel. Alternative high resistance materials may also be used.

Electron beam welding EBW may be used as an economical way to make the entire shunt resistor portion 10 including low-ohmic shunt resistor portions 11 and the high resistance portion 12. In the manufacturing process, two copper and one manganin strips are fed from reels to a welding machine as a continuous process. After the welding, individual shunt resistor portions 10 are formed by cutting the welded strip to length, usually by a stamping process.

Typical physical parameters of such shunt resistor portions 10 may be in the order of magnitude of 85 mm×36 mm with in size e.g. a 50μΩ resistance. The pin terminals 1, 2 are for voltage sensing and for PCBA 13 mounting to the low resistance portion 11 of the shunt resistor portion 10. Each of the low resistance portions 11 may comprise another terminal. The shunt resistor portion 10 can be easily used with busbar structures and corresponding bolt connections.

This kind of wide strip shaped resistors show more complicated high frequency behavior than is the case with small symmetrical round bar resistors. At higher frequencies, current flow is increasingly concentrated at the sharp corners of the strip shaped resistor. This causes phase-shifting to the current distribution and to the magnetic field around the shunt.

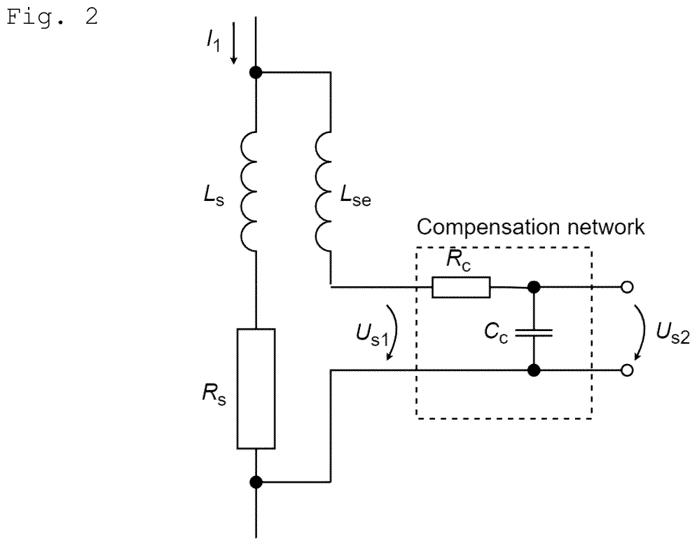

The high frequency behavior can be significantly improved by providing a shunt structure with a high resistance portion 12, in which a current return conductor is located on the other side of the strip, i.e. beneath the high resistance portion and 12 preferably opposite the PCBA 13 and as close as possible to the shunt resistor portion 10. The high resistance portion 12 can be a U-shaped structure, in which the current is distributed quite evenly in the manganin part. As this geometry also results in field canceling effects around the structure, mutual inductance to the voltage sensing part i.e. the voltage sensing inductive portion Lse shown in FIG. 2, is greatly reduced.

In order to minimize production costs, the shunt may be mounted directly between two straight busbar structures. In such circumstances, mutual coupling can be minimized by making the voltage measurement loop or rather its potential leads as small as possible by placing them tightly against the shunt metal. This may minimize noise voltages induced from stray fields. In this case with one pole compensation, phase-shifting problems may occur.

Hence, by making the sensing loop bigger and farther away from the shunt surface, its behavior may be improved. However, making the loop purposely large conflicts with the minimization of stray field effects to the circuit. Reference number 1 referring to one of the contact points suggests an optimal placement of the potential lead structure. It provides good compensation from both an inductance and a skin effect point of view.

Actual potential measurement contact points 1, 2 to the resistor are in the middle of the strip and the wires connected to the point 2 are routed across the resistor at about 20% distance of the strip width from the edge. The output signal is taken from points 1 and 3.

The error voltage present in the voltage between points 1 and 2 is cancelled out by the voltage induced in parts d-c and a-b of the path. Any voltage induced in part 2-d or 2-a is cancelled in part c-3 or respectively in b-3 by a symmetrical structure. The positioning of the wires of the sensing loop 3, b, a, 2, d, c, 3 at 20% distance of the strip width from the edge is close to the point where the imaginary component of the flux density crosses the zero line. The a,b and c,d areas, i.e. the area between the a-b part and the edge of the strip and the area between the c-d part and the opposite edge of the strip give good possibilities to fine tune the frequency response by changing the distance from the edge. In FIG. 1, this distance is indicated as about 0.2 of the total width W of the strip.

The components of the shunt resistor assembly may be provided such that there is no net flux through the total loop 3-b-a-2-d-c-3 in the normal direction of the surface. There is thus no corresponding current component flowing in the loop.

The compensation may work well even with unsymmetrical geometry 2-a-b-3 or 2-d-c-3. However, the symmetrical structure is beneficial because it has cancelling effects for both, the normal direction field from the shunt and for stray fields coming from other circuits than the shunt itself.

The sensing loop 3, b, a, 2, d, c, 3 may be arranged in a symmetrical manner. In particular, the sensing loop 3, b, a, 2, d, c, 3 may be of a rectangular shape. It may be symmetrical with regard to the direction of the current flow, i.e. the vertical direction in FIG. 1, which is perpendicular to the width direction indicated by the large arrow W.

The PCB 13 portion may be mounted directly to the shunt resistor portion 10 via contact points 1, 2 in the middle of the shunt resistor portion 10. The PCB 13 portion is indicated by the grey area in FIG. 1. The middle of the shunt resistor portion 10 may refer to its vertical centre line with respect to its width direction. Conductors of the PCB 13 may be routed across the shunt resistor portion 10 at a distance from its side edges corresponding to 20%±5% of the width of the shunt resistor portion 10, as indicated by the two small arrows W. The side edges are the edges defining the width of the shunt resistor assembly.

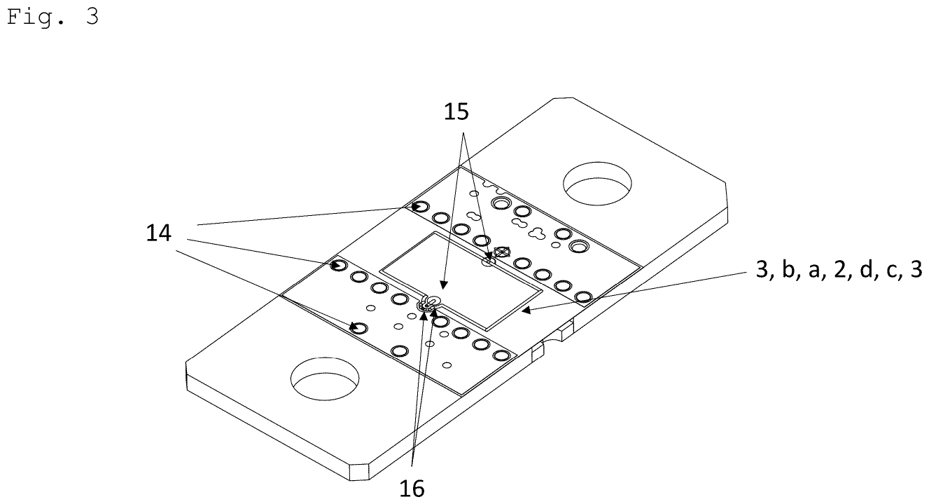

The PCB portion may comprise the sensing loop 3, b, a, 2, d, c, 3, a high frequency compensation network, a Delta-Sigma AD-converter, a current measurement circuitry, an IGBT driver and/or a drive, which are not all shown in detail in the figure. The shunt resistor portion 10 may be of a substantially rectangular shape, wherein its external edges are preferably continuous and/or straight. At least one of the contact points 1, 2 may be aligned with the sensing loop 3, b, a, 2, d, c, 3. The alignment of the contact point 1, 2 with the sensing loop 3, b, a, 2, d, c, 3 provides a symmetrical arrangement of the components, thereby enhancing the performance of the device. For example, the c-3-b part of the loop can be aligned with pin 1 such that they are all in the same line for better symmetry, as will be shown in FIG. 3. In order to achieve this, the c-3-b part of the loop may comprise a curved portion, within which the pin 1 can be positioned.

Key points regarding the invention comprise the geometry of the potential lead structure, i.e. the geometry of the sensing loop 3, b, a, 2, d, c, 3. The sensing loop's 3, b, a, 2, d, c, 3 shape can be implemented as printed circuit board PCB routes in the board, wherein the PCB is mounted directly to the shunt.

The present invention provides an economical shunt resistor assembly design with very good tolerances. It is easily implemented to commercially available resistors as the sensing terminals are provided in the middle of the strip.

The shape of the shunt may deviate from the exact shape presented in FIG. 1 to further optimize the functioning of the device. Because of different metals involved in the EBW shunt, the shape may be further optimized. The sensing loop 3, b, a, 2, d, c, 3 can be mounted as close to the shunt surface as possible. This means that there may be no gap between the PCB comprising the sensing loop 3, b, a, 2, d, c, 3 and the shunt. The loop area in the normal direction of the shunt surface is thus minimal and voltage induced from stray fields in that direction is greatly reduced.

The centre line of the strip shaped shunt resistor is at an optimal placement for signal takeout, as the normal direction field has a null point in the middle of the shunt resistor, i.e. at the vertical centre line positioned in the middle between the two vertical sides of the shunt resistor portion 10 shown in FIG. 1. The present shunt resistor assembly facilitates its connection to connectors, amplifiers, AD-converters and other front-end circuitry as wells as the placement of these components with respect to the shunt resistor portion. The location of the copper parts or low resistance portions 11 also helps to improve the performance of the device, as due to the higher conductivity of the copper, current is crowded more to the corners of the strip shaped shunt resistor rather than in the manganin portion or low resistance portion 12 and thus field intensity tends to be lower.

The invention also enhances the compensation and frequency response. The total system may or may not include the compensation pole of compensation network of FIG. 2. Some residual inductance is in many cases beneficial: While the compensation pole straightens the measurement frequency response, it attenuates unwanted noise signals induced from stray fields to the system. Additional filtering may also be provided for e.g. antialiasing purposes. The frequency response of the device can be adjusted by changing the distance of a-b, d-c lines shown in FIG. 1 from the edge of the shunt resistor. Depending on the application, the placement of the loop may be selected for the device to be purposely tuned off from the optimal flat response point. The total compensation may include both analog and digital filtering.

The principle of the presently described device can be used with resistance materials and material combinations other than manganin, including pure copper. Accordingly, the a-b/d-c distances from the edge of the shunt resistor may be varied depending on the material selection.

A U-shaped shunt resistor with a return conductor can also be used with the proposed potential lead structure. In addition to the current measurement circuitry, other circuitry may also be included to the PCB, for example IGBT drivers, a complete drive of preferably smaller current range with main current carrying tracks also provided in the same PCBA and/or a multilayer structure to differentiate the potential measurement structure and a main current part of the device.

FIG. 2 shows a model of the presently described current measurement shunt resistor assembly. This basic model for the four-terminal current measurement shunt assembly may include a frequency compensation network. The resistor model consists of a resistance Rₛ, a self-inductance Lₛ and a voltage sensing circuit inductance Lₛₑ. The voltage Uₛ1 thus has both resistive and inductive components.

Because of the involved inductivity, the system transfer function from I₁ to Uₛ₁ is zero at frequency f_{z}=Rₛ/2_{π}L_{M} where L_{M} is mutual or effective inductance between Lₛ and Lₛₑ circuits. Above the frequency of the zero point, the amplitude response rises indefinitely. Hence measures have to be made, if that area belongs to the frequency range of interest. In order to limit power dissipation in the resistor, it is desirable to use as low a value of resistance as possible. When the measuring range is from hundreds to some thousands of amperes, resistance values in the tens of microohms are practical. The inductance values can be in the nH range, so the system transfer function zero tends to occur at a relatively low frequency, creating phase shift errors even at fundamental frequencies of the output of a drive of the shunt resistor assembly.

The transfer function zero can be cancelled by adding a compensation network to the signal path. A corresponding RC-circuit may add a pole to the transfer function and by fulfilling R_{c}C_{c}=L_{M}/Rₛ, voltage Uₛ₂ may have a completely flat frequency response. Instead of an RC network, it is also possible to insert a dedicated compensation coil nearby the resistor structure so that the mutual inductance is cancelled.

The idealized model with the compensation network of FIG. 2 works well if the mechanical dimensions of the shunt resistor are small related to frequency and the structure is mechanically or geometrically symmetrical, e.g. round. For example, if the shunt resistor (Rs) is made of a round bar and its diameter is sufficiently small so that skin effects are negligible or have only minor influence.

The shunt resistor portion 10 may comprise a self-inductive portion Ls coupled in series with a resistive shunt portion Rs. The shunt resistor portion 10 may comprise a voltage sensing inductive portion Lse coupled in series with the high frequency compensation network indicated by the dashed line. The high frequency compensation network comprises an RC filter Rc, Cc to block certain output frequencies. The blocked frequencies may be selected depending on the actual requirements of the current shunt resistor assembly.

FIG. 3 is a perspective view of the current measurement shunt resistor assembly. External soldering points 14 provide mechanical connection means for connecting the shunt resistor portion 10 to the PCB portion 13 or other components. Internal soldering points 15 provide a signal connection between the shunt resistor portion 10 and the sensing loop 3, b, a, 2, d, c, 3. The Internal soldering points 15 coincide with loop points 1 and 2. Output points 16 correspond to loop point 3 and the contact point 1. These output points 16 are provided for capturing the measurement signal. The signal may continue from these points to e.g. the compensation network and to the AD-converter.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A four-terminal current measurement shunt resistor assembly comprising
a shunt resistor portion,
a sensing loop, and
a PCB portion, wherein
the shunt resistor portion comprises two low resistance portions connected by a high resistance portion and wherein the PCB portion connects the two low resistance portions to each other via two contact points.

2. The four-terminal current measurement shunt resistor assembly according to claim 1, wherein the low resistance portions are made of copper and/or that the high resistance portion is made of manganin, i.e. an alloy comprising 84.2%±2.0% copper, 12.1%±2.0% manganese, and 3.7%±2.0% nickel.

3. The four-terminal current measurement shunt resistor assembly according to claim 1, wherein the sensing loop is arranged in a symmetrical manner.

4. The four-terminal current measurement shunt resistor assembly according to claim 1, wherein the PCB portion is mounted preferably directly to the shunt resistor portion via contact points in the middle of the shunt resistor portion and/or that conductors are routed across the shunt resistor portion at a distance from its edge corresponding to 20%±5% of the width of the shunt resistor portion.

5. The four-terminal current measurement shunt resistor assembly according to claim 1, wherein the PCB portion comprises the sensing loop, a high frequency compensation network, a Delta-Sigma AD-converter, a current measurement circuitry, an IGBT driver and/or a drive.

6. The four-terminal current shunt resistor assembly according to claim 1, wherein the shunt resistor portion comprises a self-inductive portion (Lₛ) coupled in series with a resistive shunt portion (Rₛ).

7. The four-terminal current shunt resistor assembly according to claim 5, wherein the shunt resistor portion comprises a voltage sensing inductive portion (Lₛₑ) coupled in series with the high frequency compensation network.

8. The four-terminal current shunt resistor assembly according to claim 7, wherein the high frequency compensation network comprises an RC filter (Rc, Cc) to block certain output frequencies.

9. The four-terminal current measurement shunt resistor assembly according to claim 1, wherein the shunt resistor portion is of a substantially rectangular shape, wherein its external edges are preferably continuous and straight.

10. The four-terminal current measurement shunt resistor assembly according to claim 1, wherein one of the contact points is aligned with the sensing loop.

11. The four-terminal current measurement shunt resistor assembly according to claim 2, wherein the sensing loop is arranged in a symmetrical manner.

12. The four-terminal current measurement shunt resistor assembly according to claim 2, wherein the PCB portion is mounted preferably directly to the shunt resistor portion via contact points in the middle of the shunt resistor portion and/or that conductors are routed across the shunt resistor portion at a distance from its edge corresponding to 20%±5% of the width of the shunt resistor portion.

13. The four-terminal current measurement shunt resistor assembly according to claim 3, wherein the PCB portion is mounted preferably directly to the shunt resistor portion via contact points in the middle of the shunt resistor portion and/or that conductors are routed across the shunt resistor portion at a distance from its edge corresponding to 20%±5% of the width of the shunt resistor portion.

14. The four-terminal current measurement shunt resistor assembly according to claim 2, wherein the PCB portion comprises the sensing loop, a high frequency compensation network, a Delta-Sigma AD-converter, a current measurement circuitry, an IGBT driver and/or a drive.

15. The four-terminal current measurement shunt resistor assembly according to claim 3, wherein the PCB portion comprises the sensing loop, a high frequency compensation network, a Delta-Sigma AD-converter, a current measurement circuitry, an IGBT driver and/or a drive.

16. The four-terminal current measurement shunt resistor assembly according to claim 4, wherein the PCB portion comprises the sensing loop, a high frequency compensation network, a Delta-Sigma AD-converter, a current measurement circuitry, an IGBT driver and/or a drive.

17. The four-terminal current shunt resistor assembly according to claim 2, wherein the shunt resistor portion comprises a self-inductive portion (Lₛ) coupled in series with a resistive shunt portion (Rₛ).

18. The four-terminal current shunt resistor assembly according to claim 3, wherein the shunt resistor portion comprises a self-inductive portion (Lₛ) coupled in series with a resistive shunt portion (Rₛ).

19. The four-terminal current shunt resistor assembly according to claim 4, wherein the shunt resistor portion comprises a self-inductive portion (Lₛ) coupled in series with a resistive shunt portion (Rₛ).

20. The four-terminal current shunt resistor assembly according to claim 5, wherein the shunt resistor portion comprises a self-inductive portion (Lₛ) coupled in series with a resistive shunt portion (Rₛ).
